(19) United States
(12) Patent Application Publication
(10) Pub. No.: US 2025/0330001 A1
(43) Pub. Date: Oct. 23, 2025

(54) ELECTRICAL JUNCTION BOX

(71) Applicant: Sumitomo Wiring Systems, Ltd., Yokkaichi-shi, Mie (JP)

(72) Inventors: Kiyofumi KAWAGUCHI, Yokkaichi-Shi, Mie (JP); Tatsuya FUJISAKA, Yokkaichi-Shi, Mie (JP)

(73) Assignee: Sumitomo Wiring Systems, Ltd., Yokkaichi-shi, Mie (JP)

(21) Appl. No.: 18/870,096

(22) PCT Filed: May 17, 2023
(86) PCT No.: PCT/JP2023/018476

§ 371 Date: Nov. 27, 2024

(30) Foreign Application Priority Data
Jun. 1, 2022 (JP) 2022-089777

(51) Int. Cl. H02G 3/08

(52) U.S. Cl. CPC H02G 3/081

(57) ABSTRACT

Provided is an electrical junction box that includes a bottom wall that comes into contact with a mount target such as a battery pack, and a ceiling wall opposing the bottom wall, an inner rib protrudes from an inner surface of the ceiling wall, and a second outer rib protrudes from an outer side surface that is opposite to the inner surface of the ceiling wall.

### CROSS-REFERENCE TO RELATED APPLICATIONS

This application is the U.S. national stage of PCT/JP2023/018476 filed on May 17, 2023, which claims priority of Japanese Patent Application No. JP 2022-089777 filed on Jun. 1, 2022, the contents of which are incorporated herein.

### TECHNICAL FIELD

The present disclosure relates to an electrical junction box that includes a board.

### BACKGROUND

Heretofore, an electrical junction box that accommodates electronic components such as fuses and relays is mounted in vehicles.

The electrical junction box includes a housing, and the housing is constituted by a first case that is open on one surface side thereof and accommodates the electronic components, and a second case that covers the one surface side of the first case that is open, for example (see JP 2016-208561A).

As the number of electronic components that need to be accommodated increases due to diversification of functions in vehicles, the sizes of electrical junction boxes have also increased. However, as the number of electronic components increases and the sizes of electrical junction boxes increase, the electrical junction boxes have become likely to be affected by heat generated in electronic components when energized. That is to say, there has been a problem in that warping occurs in an end portion in the lengthwise direction of the electrical junction box due to a difference in amount of thermal expansion (amount of contraction) caused by heat generated in electronic components.

However, with the electrical junction box in JP 2016-208561A, in which such a problem is not taken into consideration, the problem cannot be addressed.

In view of this, an object of the present disclosure is to provide an electrical junction box that can suppress the occurrence of warping due to heat generated in electronic components.

### SUMMARY

An electrical junction box according to an embodiment of the present disclosure is an electrical junction box that includes: a first wall that comes into contact with a mount target, and a second wall that includes a surface that opposes the first wall and an inner rib that protrudes from the surface, and an outer rib protrudes from an opposite surface that is opposite to the opposing surface of the second wall.

### Advantageous Effects

According to the present disclosure, it is possible to provide an electrical junction box that can suppress the occurrence of warping due to heat generated in electronic components.

### BRIEF DESCRIPTION OF THE DRAWINGS

FIG. 1 is a perspective view of an electrical junction box according to an embodiment of the present disclosure.

FIG. 2A is a plan view of the electrical junction box according to the embodiment.

FIG. 2B is a side view of the electrical junction box according to the embodiment.

FIG. 3 is an exploded view of the electrical junction box according to the embodiment.

FIG. 4 is a partial perspective view showing a second outer rib provided on one end portion of a ceiling wall, in the electrical junction box according to the embodiment.

FIG. 5 is a longitudinal cross-sectional view taken along the V-V line in FIG. 4.

FIG. 6 is a partial cross-sectional view schematically showing the one end portion of the ceiling wall on which a second outer rib is provided, in the electrical junction box according to the embodiment.

FIG. 7 is a diagram showing a result of simulating warping of the electrical junction box caused by a difference in thermal expansion.

### DETAILED DESCRIPTION OF PREFERRED EMBODIMENTS

First, embodiments of the present disclosure will be listed and described. In addition, at least some of the embodiments described below may be combined as appropriate.

An electrical junction box according to an embodiment of the present disclosure is an electrical junction box that includes: a first wall that comes into contact with a mount target, and a second wall that includes a surface that opposes the first wall and an inner rib that protrudes from the surface, and an outer rib protrudes from an opposite surface that is opposite to the opposing surface of the second wall.

According to such an embodiment, an inner rib is provided on the opposing surface of the second wall, and an outer rib is provided on the opposite surface that is opposite to the opposing surface. Therefore, a difference in contraction that has occurred between the second wall and the inner rib caused by a difference in amount of heat generated during an operation remains is offset by a difference in contraction that has occurred between the second wall and the outer rib, and it is possible to suppress the occurrence of warping of the second wall.

In the electrical junction box according to the embodiment of the present disclosure, the inner rib and the outer rib each have a shape of a plate, and a thickness of the second wall is larger than thicknesses of the inner rib and the outer rib.

According to such an embodiment, the thickness of the second wall is larger than the thicknesses of the inner rib and the outer rib, and thus, heat that has generated during an operation is likely to remain in the second wall more than the inner rib and the outer rib, and a difference in amount of heat that remains in this manner causes a difference in contraction that is a cause of warping. However, a difference in contraction that has occurred between the second wall and the inner rib is offset by a difference in contraction that has occurred between the second wall and the outer rib, thus suppressing the occurrence of warping of the second wall.

In the electrical junction box according to the embodiment of the present disclosure, an end portion in a lengthwise direction of the second wall is inclined so as to approach the first wall toward a leading end of the second wall, a plurality of the outer ribs are provided, and lengths of the outer ribs in an opposing direction of the first wall and the second wall increase toward a leading end in the lengthwise direction of the second wall.

According to such an embodiment, the end portion of the second wall is inclined so as to approach the first wall toward the leading end thereof, and the lengths of the outer ribs in the opposing direction of the first wall and the second wall increase toward the leading end in the lengthwise direction thereof. Therefore, a difference in contraction that has occurred between the second wall and the inner rib and a difference in contraction that has occurred between the second wall and the outer ribs are set to the same degree and are offset, thereby suppressing the occurrence of warping of the second wall.

In the electrical junction box according to the embodiment of the present disclosure, the outer ribs are provided in an end portion in the lengthwise direction of the second wall.

According to such an embodiment, the outer ribs are provided in the end portion of the second wall in which significant warping occurs. Therefore, it is possible to more efficiently suppress the occurrence of warping of the second wall.

In the electrical junction box according to the embodiment of the present disclosure, a side wall extending in the opposing direction is disposed around an edge of the second wall, and a distance between the first wall and a leading end of the side wall in the opposing direction is fixed.

According to such an embodiment, the distance between the first wall and the leading end of the side wall in the opposing direction is fixed. Thus, it is possible to prevent a local decrease in the strength of the end portion of the second wall due to the end portion of the second wall being inclined so as to approach the first wall.

An electrical junction box according to an embodiment of the present disclosure will be described below with reference to the drawings. Note that the present disclosure is not limited to illustrations of these, but is indicated by the claims, and is intended to include all modifications that are within the meanings and the scope that are equivalent to those of the claims.

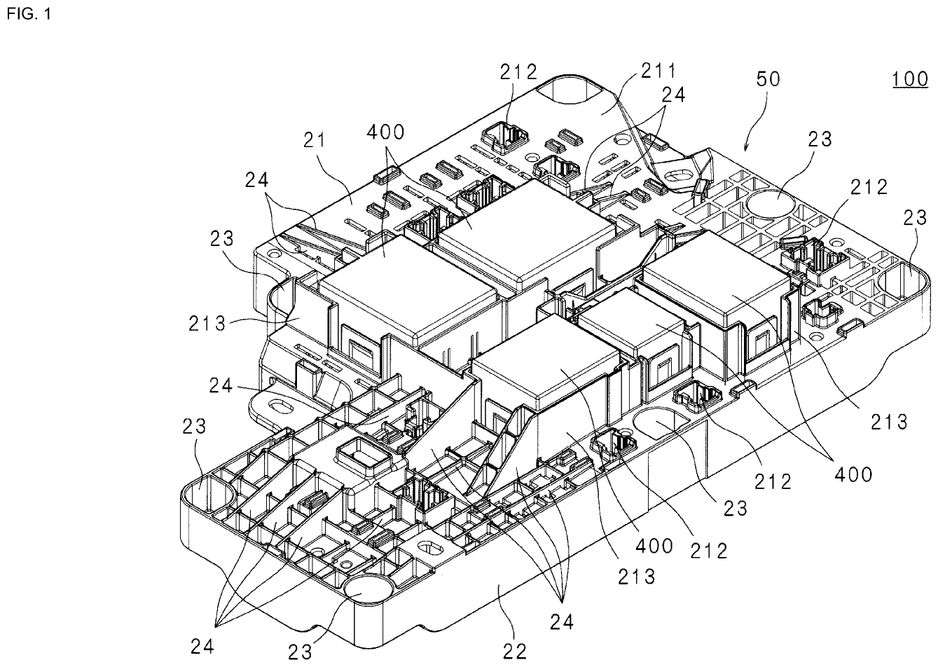

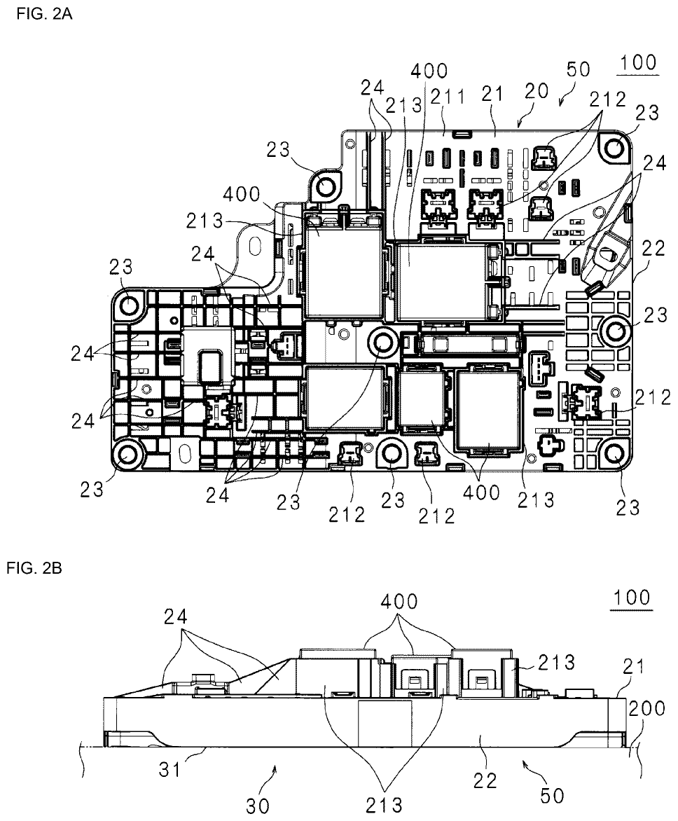

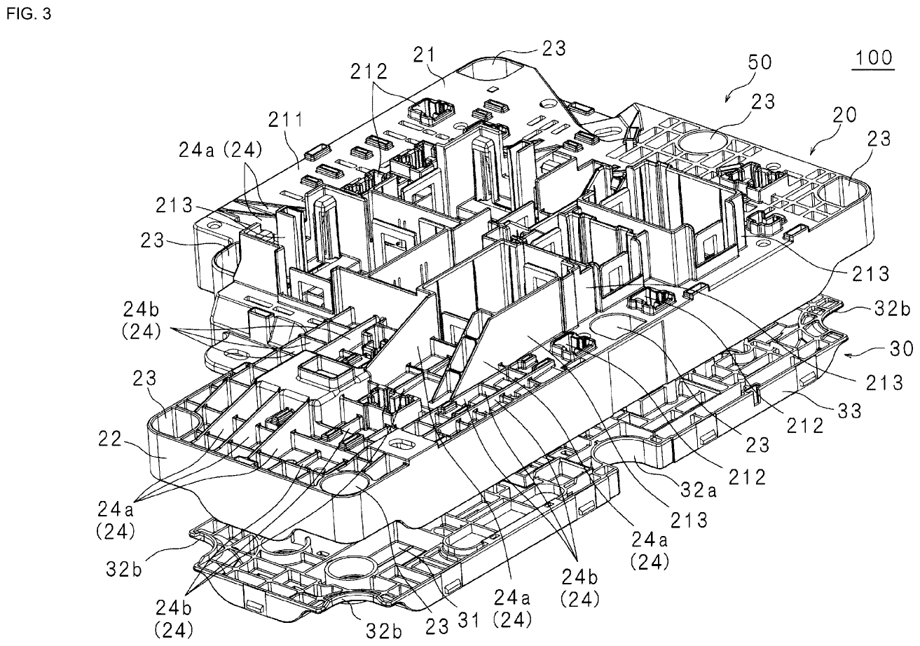

FIG. 1 is a perspective view of an electrical junction box 100 according to an embodiment of the present disclosure, FIGS. 2A and 2B are a plan view and a side view of the electrical junction box 100 according to the embodiment, and FIG. 3 is an exploded view of the electrical junction box 100 according to the embodiment. FIG. 2A is a plan view of the electrical junction box 100, and FIG. 2B is a side view of the electrical junction box 100.

The electrical junction box 100 is attached to the outer side of a mount target such as a battery pack 200 (see FIG. 2) of an EV (Electric Vehicle), for example. For convenience of description, FIG. 2B shows a state where the electrical junction box 100 is attached to the battery pack 200.

The electrical junction box 100 includes a housing 50 that accommodates a fuse, a board, and the like. The housing 50 is a flattened housing, is substantially rectangular in plan view, and has a shape in which one corner of one end portion in the lengthwise direction is notched in a stepped manner. The housing 50 is made of a resin, for example, and is constituted by a lower case 30 that is attached to the mount target, and an upper case 20 that covers the lower case 30. For convenience of description, the following description is given in which the upper case 20 side is the upper side, and the lower case 30 side is the lower side.

The lower case 30 has a shape of a box in which one surface on the upper case 20 side is open. The lower case 30 includes a bottom wall 31 (first wall) whose outer side surface comes into contact with the mount target, and a side wall 33 extending perpendicularly from an edge of the bottom wall 31 to the upper case 20 side. Ribs are formed at a plurality of locations inside the lower case 30 (see FIG. 3).

Recessed portions 32b are formed in the two end portions in the lengthwise direction of the bottom wall 31 of the lower case 30, and a recessed portion 32a is formed in an intermediate portion. The recessed portion 32a and the recessed portions 32b are formed at positions corresponding to fastening portions 23 (mount portions) of the upper case 20, which will be described later.

Specifically, the recessed portions 32b are respectively formed in the two corners of each of the two end portions of the lower case 30. The recessed portions 32b are substantially rectangular in plan view, the side wall 33 is bent at substantially the right angle in the recessed portions 32b, and the corners of each recess are chamfered (see FIG. 3).

In addition, the recessed portion 32a is formed in an intermediate portion on a longer edge side of the lower case 30. The recessed portion 32a is substantially rectangular in plan view. In the recessed portion 32a, the side wall 33 is recessed inward in the lower case 30, and the corners of the recess are chamfered (see FIG. 3).

The upper case 20 has a shape of a box in which the one surface on the lower case 30 side is open. The lengths of the upper case 20 in the lengthwise direction and in the width direction orthogonal to the lengthwise direction are slightly larger than those of the lower case 30, and the upper case 20 covers the lower case 30.

In addition, the upper case 20 includes a ceiling wall 21 (second wall) that opposes the bottom wall 31 of the lower case 30, and a side wall 22 that is disposed around an edge of the ceiling wall 21 and extends in the up-down direction. The fastening portions 23 for attaching the upper case 20 (the housing 50) to the mount target are provided in the two end portions and an intermediate portion in the lengthwise direction of the upper case 20.

Specifically, the fastening portions 23 are respectively provided at the two

corners of one end portion in the lengthwise direction of the upper case 20, and are respectively provided at the two corners of the other end portion and between the two corners. Furthermore, also in the intermediate portion in the lengthwise direction of the upper case 20, three fastening portions, namely the fastening portions 23 are aligned in the width direction. The fastening portions 23 protrude from the inner surface 214 (opposing surface) of the ceiling wall 21 that opposes the bottom wall 31 (see FIG. 5), and the fastening portions 23 other than the one fastening portion 23 in the substantially central portion of the ceiling wall 21 are provided in the vicinity of the side wall 22 (see FIG. 2A).

A plurality of inner ribs 25 protrude from the inner surface 214 of the ceiling wall 21 (see FIG. 5). The plurality of inner ribs 25 are aligned in the lengthwise direction, and the inner ribs 25 each has a shape of a plate extending in the width direction. In addition, the thickness of each inner rib 25 is smaller than the thickness of the ceiling wall 21.

The fastening portions 23 have a bottomed tubular shape, and are open on the ceiling wall 21 side. In addition, fixing through holes 231 that are used when attaching the housing 50 to the mount target are formed in the bottoms of the fastening portions 23 (see FIG. 5). The housing 50 (the electrical junction box 100) can be attached to the mount target by inserting screws into the fixing through holes 231 of the fastening portions 23 from the mount target and threading the screws into nuts (not illustrated) provided in the fastening portions 23.

As described above, inside the recessed portion 32a and the recessed portions 32b of the lower case 30, the fastening portions 23 of the upper case 20 are respectively disposed.

Various connection portions 212 for connection to another apparatus are provided at a plurality of locations of an outer surface 211 (opposite surface) on the opposite side to the inner surface 214 of the ceiling wall 21. In addition, a plurality of mount seats 213 for relays 400 are provided in a substantially central portion of the outer surface 211 of the ceiling wall 21, and a plurality of relays 400 are mounted thereto. For convenience, FIG. 3 does not illustrate the relays 400.

Moreover, a plurality of outer ribs 24 protrude from the outer surface 211 of the ceiling wall 21. The outer ribs 24 include first outer ribs 24a for preventing warping caused by gravity and second outer ribs 24b (outer ribs) for preventing warping caused by a difference in thermal expansion as will be described later.

The first outer ribs 24a have a shape of a triangular plate, and are provided mainly in peripheral edge portions of the ceiling wall 21. That is to say, the length in the up-down direction of each of the first outer ribs 24a decreases toward the peripheral edge from a central portion of the ceiling wall 21. As described above, the first outer ribs 24a suppress the occurrence of warping of the ceiling wall 21 due to the weight of the relays 400 (see FIGS. 1 and 2) mounted in the central portion.

The second outer ribs 24b have a shape of a plate, and are provided in an end portion in the lengthwise direction of the ceiling wall 21. For convenience, in the present embodiment, a case will be described in which, as an example, the second outer ribs 24b are provided only in one end portion of the ceiling wall 21, but there is no limitation thereto, and the second outer ribs 24b may be provided in two end portions. The thickness of each second outer rib 24b is smaller than the thickness of the ceiling wall 21.

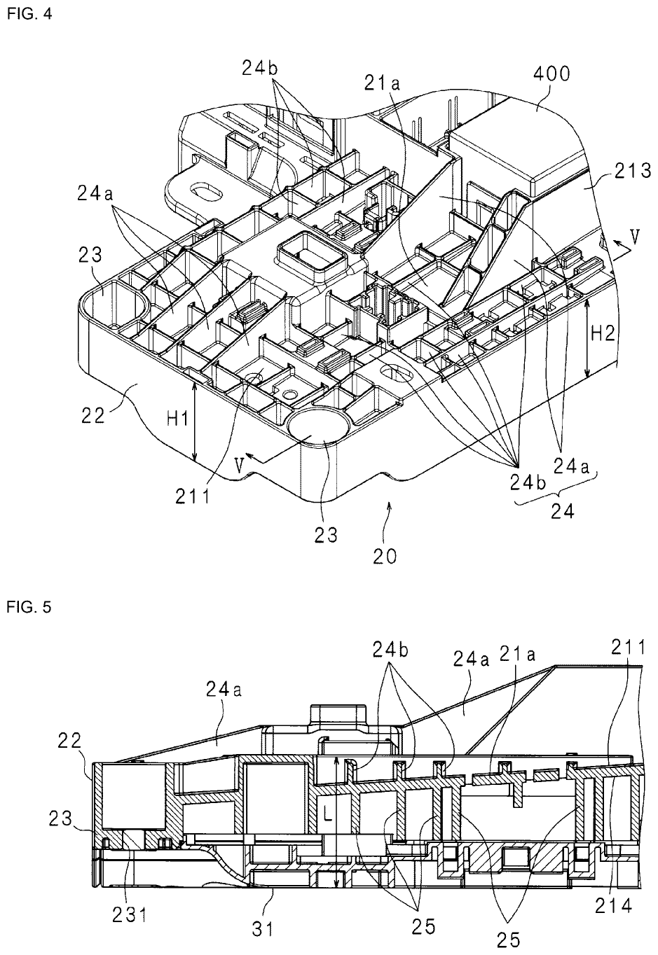

FIG. 4 is a partial perspective view showing the second outer ribs 24b provided in one end portion 21a of the ceiling wall 21 in the electrical junction box 100 according to the embodiment, and FIG. 5 is a longitudinal cross-sectional view taken along the line V-V in FIG. 4.

As described above, the second outer ribs 24b are provided in the one end portion 21a of the ceiling wall 21. The second outer ribs 24b are provided at positions corresponding to the inner ribs 25 in the up-down direction, or in the vicinities of the corresponding positions. The lengths (hereinafter, also referred to as a “height”) in the up-down direction of the second outer ribs 24b increase toward the peripheral edge of the ceiling wall 21.

As shown in FIG. 5, the one end portion 21a in the lengthwise direction of the ceiling wall 21 is inclined downward. That is to say, the one end portion 21a of the ceiling wall 21 in which the second outer ribs 24b are provided is inclined so as to approach the bottom wall 31 of the lower case 30 toward the peripheral edge thereof, and the distance between a portion of the ceiling wall 21 other than the one end portion 21a and the bottom wall 31 is kept fixed. In addition, distances L between the bottom wall 31 and the upper ends of all of the second outer ribs 24b (hereinafter, referred to as “upper end distances L”) are substantially the same.

As described above, while the upper end distances L for the plurality of second outer ribs 24b are the same, the one end portion 21a of the ceiling wall 21 is inclined downward toward the peripheral edge thereof, and thus the length in the up-down direction of each of the second outer ribs 24b increases toward the peripheral edge of the ceiling wall 21.

In addition, as described above, the one end portion 21a of the ceiling wall 21 is inclined downward toward the peripheral edge thereof, but, in the up-down direction, the distance between the bottom wall 31 of the lower case 30 and the leading end of the side wall 22 of the upper case 20, that is to say the upper end of the side wall 22 is fixed.

That is to say, as shown in FIG. 4, a distance H1 between the bottom wall 31 and the upper end of the side wall 22 along the peripheral edge of the one end portion 21a of the ceiling wall 21 in the lengthwise direction, that is to say along a shorter edge of the ceiling wall 21 is the same as a distance H2 between the bottom wall 31 and the upper end of the side wall 22 along a longer edge of the ceiling wall 21.

Since the electrical junction box 100 according to the embodiment has such a configuration, as described above, the second outer ribs 24b can suppress the occurrence of warping of the ceiling wall 21 caused by a difference in thermal expansion. Detailed description will be given below.

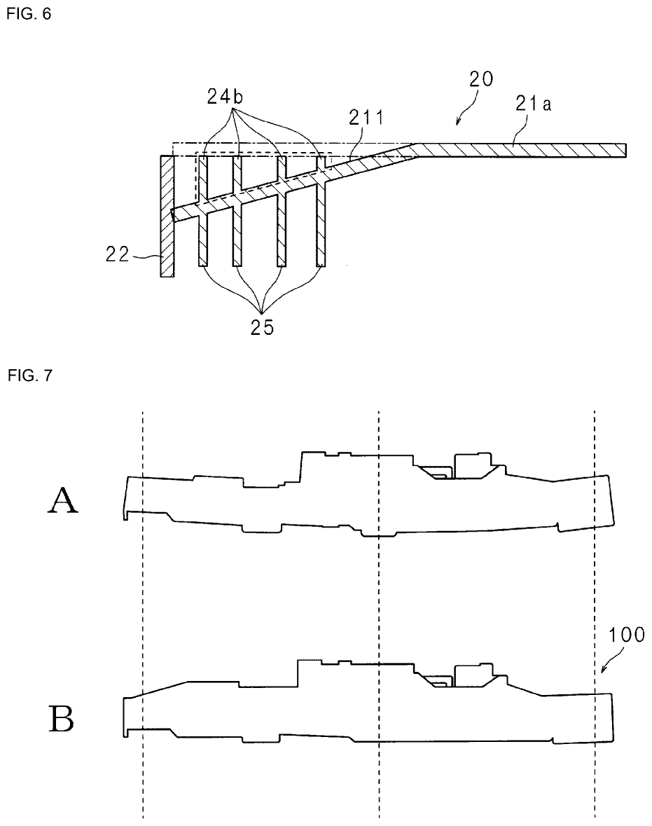

FIG. 6 is a partial cross-sectional view schematically showing the one end portion 21a of the ceiling wall 21 in which the second outer ribs 24b are provided, in the electrical junction box 100 according to embodiment, and FIG. 7 is a diagram showing a result of simulating warping of the electrical junction box 100 caused by a difference in thermal expansion. 1. For convenience, FIG. 7 shows only contours of the electrical junction box. In addition, FIG. 7A shows a case where the one end portion 21a of the ceiling wall 21 is not inclined, and the second outer ribs 24b are not provided, and FIG. 7B shows a case where the one end portion 21a of the ceiling wall 21 is inclined, and the second outer ribs 24b are provided, that is to say a case of the electrical junction box 100 according to the present embodiment.

In a case where the one end portion 21a of the ceiling wall 21 is not inclined, and only the inner ribs 25 and the first outer ribs 24a are provided (see the one-dot chain line in FIG. 6), a problem occurs in that an end portion of the ceiling wall 21 is warped to the upper side where the inner ribs 25 are not provided, due to heat generated in the relay 400 or the like while the electrical junction box 100 is in operation (see FIG. 7A).

It is assumed that the cause for this is that, since the ceiling wall 21 is thicker than the inner ribs 25, and is in direct contact with a heat source (for example, the relay 400) and the like, the ceiling wall 21 retains a large amount of generated heat, while the inner ribs 25 are thinner and are likely to be air-cooled, and thus a contraction (thermal expansion) difference occurs between the ceiling wall 21 and the inner ribs 25.

In contrast, in the electrical junction box 100 according to the present embodiment, as described above, the second outer ribs 24b are formed on the outer surface 211 of the ceiling wall 21. Thus, a difference in contraction that has occurred between the ceiling wall 21 and the inner ribs 25 is offset by a difference in contraction that has occurred between the ceiling wall 21 and the second outer ribs 24b, and it is possible to suppress the occurrence of warping of the ceiling wall 21.

As shown in FIG. 7B, in the electrical junction box 100 according to the present embodiment, the second outer ribs 24b are formed on the outer surface 211 of the ceiling wall 21, and thus the occurrence of warping of the ceiling wall 21 is suppressed.

Furthermore, in the electrical junction box 100 according to the present embodiment, as described above, the one end portion 21a of the ceiling wall 21 in which the second outer ribs 24b are provided is inclined downward toward the peripheral edge thereof, and thus the heights of the second outer ribs 24b increase toward the peripheral edge of the ceiling wall 21 (see the dashed line portion in FIG. 6), making it possible to increase the air-cooling effect. Thus, it is possible to more appropriately suppress the occurrence of warping of the ceiling wall 21.

In this manner, in the electrical junction box 100 according to the present embodiment, the heights of the second outer ribs 24b are ensured by the one end portion 21a of the ceiling wall 21 being inclined downward, and thus it is possible to suppress the heights of the second outer ribs 24b, and reduce the size of the electrical junction box 100.

Moreover, in the electrical junction box 100 according to the present embodiment, as described above, the second outer ribs 24b are provided in the end portion of the ceiling wall 21 in which warping occurs. In this manner, by providing the second outer ribs 24b mainly at a location in the ceiling wall 21 where warping occurs, it is possible to more efficiently suppress the occurrence of warping of the ceiling wall 21 while reducing the size of the electrical junction box 100 according to the embodiment.

Note that, in the electrical junction box 100 according to the present embodiment, as described above, while the one end portion 21a of the ceiling wall 21 is inclined downward toward the peripheral edge thereof, the distance between the bottom wall 31 and the leading end of the side wall 22 of the upper case 20 in the up-down direction is fixed. Thus, in the one end portion 21a of the ceiling wall 21, it is possible to suppress a local decrease in the strength of the upper case 20.

The embodiment disclosed herein is exemplary in all respects and should not be interpreted as limiting in any manner. The scope of the present disclosure is defined not by the foregoing meanings, but is defined by the claims, and is intended to include all modifications that are within the meanings and the scope that are equivalent to those of the claims.

Matters described in the embodiment can be combined with each other. In addition, the independent claim and dependent claims described in CLAIMS can be combined with each other in any combination regardless of a reference format. Furthermore, a format in which a claim that refers to other two or more claims is written (multi claim format) is adopted for CLAIMS, but there is no limitation thereto. Claims may be written in a format in which a multi claim that refers to at least one multi claim (multi-multi claim) is written.

1. An electrical junction box that includes: a first wall that comes into contact with a mount target; and a second wall that includes a surface that opposes the first wall and an inner rib that protrudes from the surface,
wherein an outer rib protrudes from an opposite surface that is opposite to the opposing surface of the second wall.

2. The electrical junction box according to claim 1,
wherein the inner rib and the outer rib each have a shape of a plate, and
a thickness of the second wall is larger than thicknesses of the inner rib and the outer rib.

3. The electrical junction box according to claim 1, further including;
wherein an end portion in a lengthwise direction of the second wall is inclined so as to approach the first wall toward a leading end of the second wall,
a plurality of the outer ribs are provided, and
lengths of the outer ribs in an opposing direction of the first wall and the second wall increase toward a leading end in the lengthwise direction of the second wall.

4. The electrical junction box according to claim 3,
wherein the outer ribs are provided in an end portion in the lengthwise direction of the second wall.

5. The electrical junction box according to claim 3,
wherein a side wall extending in the opposing direction is disposed around an edge of the second wall, and a distance between the first wall and a leading end of the side wall in the opposing direction is fixed.

6. The electrical junction box according to claim 2, further including;
wherein an end portion in a lengthwise direction of the second wall is inclined so as to approach the first wall toward a leading end of the second wall,
a plurality of the outer ribs are provided, and
lengths of the outer ribs in an opposing direction of the first wall and the second wall increase toward a leading end in the lengthwise direction of the second wall.
